(19) United States
(12) Patent Application Publication
(10) Pub. No.: US 2002/0023246 A1
(43) Pub. Date: Feb. 21, 2002

(54) Combination reed-solomon and turbo coding

(76) Inventor: Gary Q. Jin, Kanata (CA)

Correspondence Address: MARKS AND CLERK, P O BOX 957, STATION B, 55 METCALFE STREET, SUITE 1380, OTTAWA, ON, K1P5S7, CA

(21) Appl. No.: 09/925,485

(22) Filed: Aug. 10, 2001

(30) Foreign Application Priority Data
Aug. 10, 2000 (GB) 0019545.3

(51) Int. Cl. H03M 13/03

(52) U.S. Cl. 714/755; 714/792; 714/784

(57) ABSTRACT

A decoder for use in a data communication system for decoding a stream of data which has been convolutionally and Reed-Solomon encoded is provided. The decoder has a trellis decoder for performing at least one iteration for decoding the stream of data. The Reed-Solomon decoder is provided for further decoding the encoded stream of data after the trellis decoder is stopped, the Reed-Solomon decoder including syndrome calculating means for calculating syndromes after each iteration of the trellis decoder. The decoder also includes control means for stopping the trellis decoder from performing another iteration when all of the syndromes calculated in the syndrome calculation means are zero.

The present invention relates to a data communication system with a combination trellis/Reed-Solomon encoder/decoder and in particular to a decoder wherein partial results from the Reed-Solomon decoder are used in determining whether to stop the trellis decoder from performing additional iterations.

In the field of data communication recent efforts have been made to increase the rate of data transmission without sacrificing the available bandwidth. As a result, high level modulation schemes, e.g. Quadrature Amplitude Modulation, have been developed. Unfortunately, these high level modulation schemes are greatly effected by noise and other transmission factors. Accordingly, several error correcting techniques have been utilized to minimize or eliminate errors created by these factors. Trellis codes, e.g. turbo codes, are useful in correcting errors caused by noise etc, however, they are susceptible to producing burst errors. To combat these burst errors, conventional devices utilize Reed-Solomon techniques in combination with the trellis codes. Several attempts have been made to increase the efficiency of combined Reed-Solomon and trellis codes, such as those disclosed in U.S. Pat. No. 3,988,677 (Fletcher et al), U.S. Pat. No. 5,511,096 (Huang & Heegard), U.S. Pat. No. 5,363,408 (Paik et al), and U.S. Pat. No. 6,034,996 (Herzberg).

Typically, trellis codes are designed for the worst case scenario and, therefore, require several iterations to produce a high performance output. However, a trellis code is a block operation code and in many cases the latter iterations are overkill. Moreover, in most cases only a few iterations are required to obtain the desired signal-to-noise ratio (SNR) performance. The trellis decoder always consumes a great deal of power in the chip. Accordingly, it would be highly advantageous if the number of iterations performed could be adaptively controlled. However, the decoders themselves have no mechanism to stop before all of the programmed iterations are performed. On the other hand, Reed-Solomon decoders have the ability to detect the number of error bits in the received data.

An object of the present invention is to combine the power of trellis codes and the error detection feature of the Reed-Solomon codes, whereby a desired bit error rate (BER) is achieved using the minimum number of iterations.

Accordingly, the present invention relates to a decoder for use in a data communication system for decoding a stream of data which has been convolutionally and Reed-Solomon encoded, comprising: a trellis decoder for performing at least one iteration for decoding the stream of data; a Reed-Solomon decoder for further decoding the encoded stream of data after the trellis decoder is stopped, and including syndrome calculating means for calculating syndromes after every iteration of the trellis decoder; and control means for stopping the trellis decoder from performing another iteration when all of the syndromes calculated in the syndrome calculation means are zero.

Another aspect of the invention relates to a method for use in a data communication system for decoding a stream of data which has been convolutionally and Reed-Solomon encoded, comprising the steps of: trellis decoding the stream of data during at least one iteration through a trellis decoder; calculating Reed-Solomon syndromes after every iteration of the trellis decoder; stopping the trellis decoder from performing another iteration if all of the Reed-Solomon syndromes are zero; and Reed-Solomon decoding the encoded stream of data, after the trellis decoder is stopped, in a Reed-Solomon decoder.

The invention will be described in greater detail with reference to the accompanying drawings, which illustrate preferred embodiments of the invention and wherein:

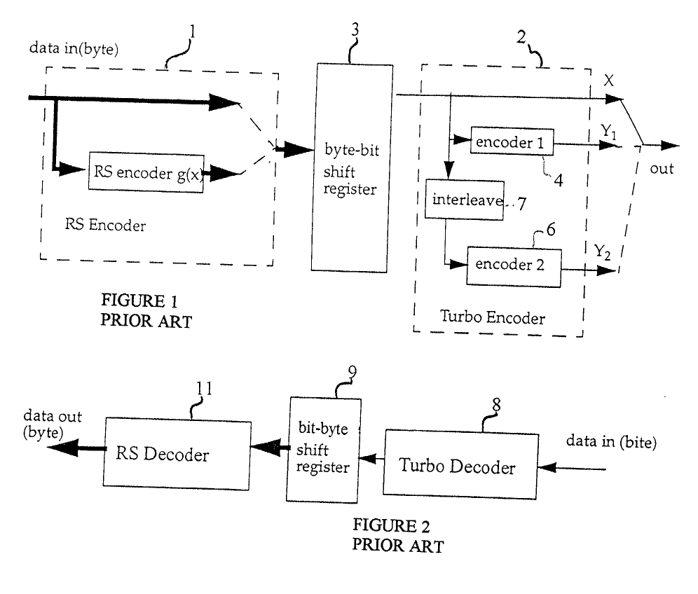

FIG. 1 is a block diagram of a conventional trellis/Reed-Solomon encoder;

FIG. 2 is a block diagram of a conventional trellis/Reed-Solomon decoder;

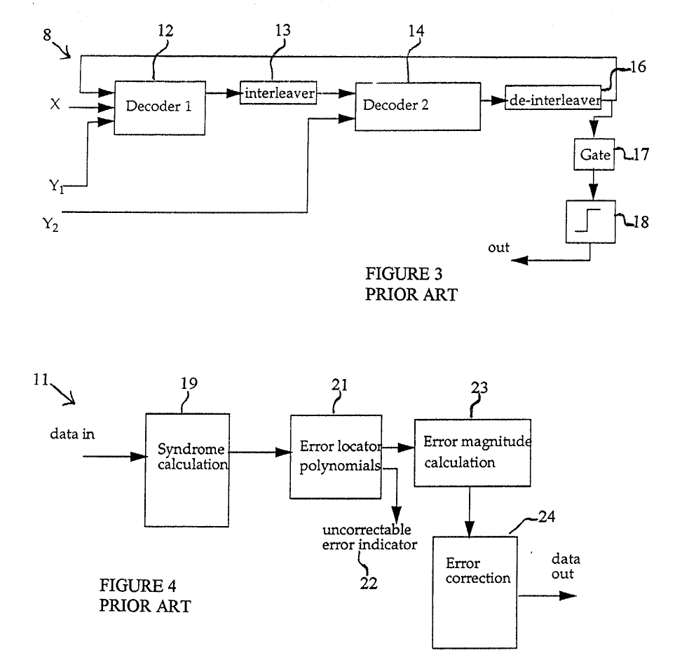

FIG. 3 is a block diagram of a conventional trellis decoder;

FIG. 4 is a block diagram of a conventional Reed-Solomon decoder;

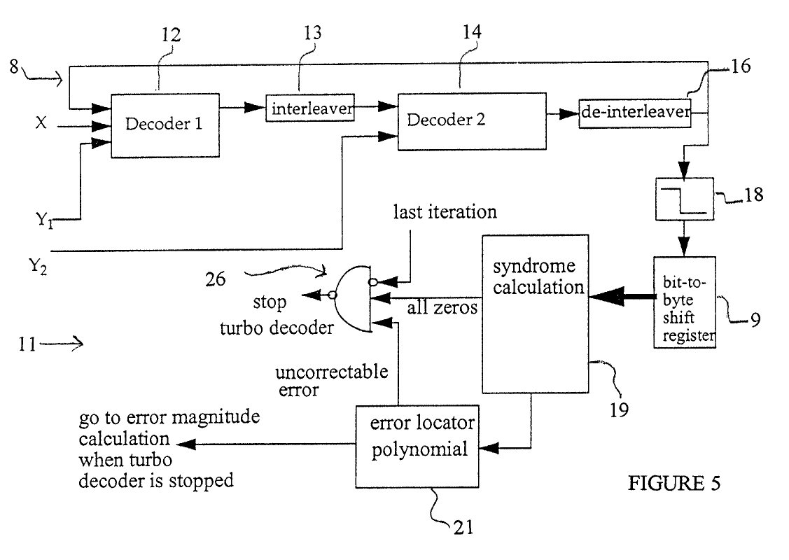

FIG. 5 is a block diagram of a combined Reed-Solomon/trellis decoder according to a first embodiment of the present invention;

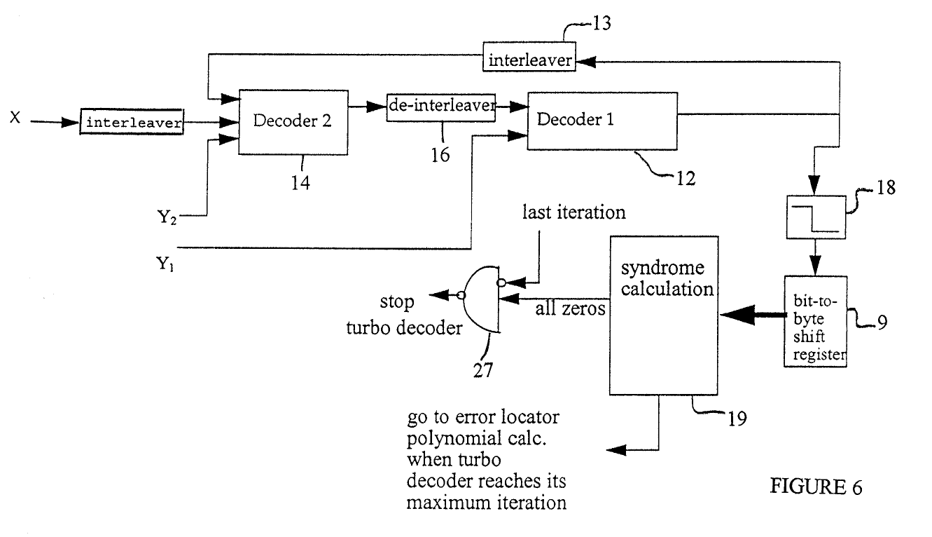

FIG. 6 is a block diagram of a combined Reed-Solomon/trellis decoder according to a second embodiment of the present invention; and

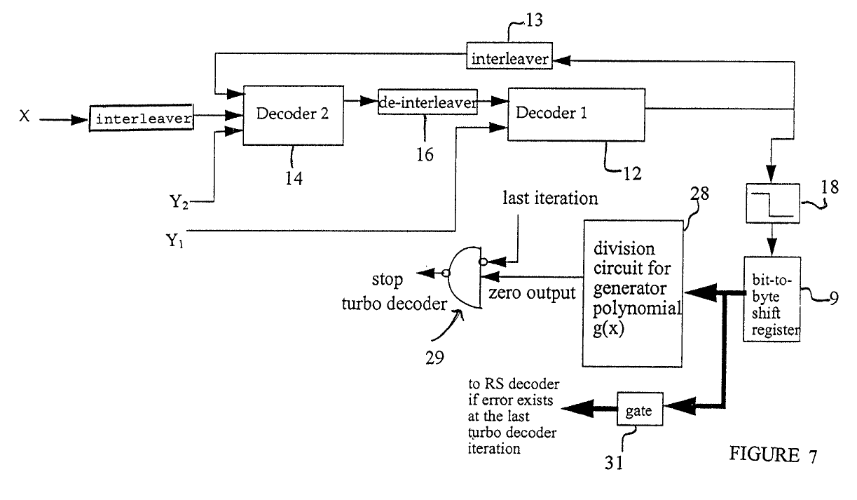

FIG. 7 is a block diagram of a combined Reed-Solomon/trellis decoder according to a third embodiment of the present invention.

As seen in FIG. 1, in a conventional transmitter the Reed-Solomon (RS) encoder 1 precedes the trellis encoder 2, and the two encoders are dealt with separately. The RS encoder 1 takes a block of data, grouped into bytes and combined with a certain number of error-checking data bytes, created by passing all data bytes through an encoder polynomial g(X). The output of the RS encoder 1 is also byte oriented. The data is then passed through a parallel to series shift register 3, which takes the data bytes, converts them into data bits, and transfers the data bits to the trellis encoder 2. In the illustrated systems, both conventional and novel, the trellis encoder and decoder is a turbo encoder/and turbo decoder, respectively.

The turbo encoder 2 includes a first encoder 4, which receives normal data input, and a second encoder 6, which receives interleaved data input. The data is passed through an interleaver 7 before reaching the encoder 6. The output of the turbo encoder 2 consists of straight data X, encoded data Y₁, and interleaved encoded data Y₂.

The conventional receiver (FIG. 2) includes a turbo decoder 8, a bit-byte shift register 9, and a RS decoder 11.

With reference to FIG. 3, the turbo decoder includes a first decoder 12, which receives the transmitted data X and Y₁. The output of the first decoder 12 is transferred through an interleaver 13, similar to interleaver 7, to a second decoder 14. The second decoder 14 also receives the transmitted data Y₂. The output of the second decoder 14 is transferred through a de-interleaver 16 and back to the first decoder 12 for another iteration. Both decoders take soft input and produce soft output. After a certain number of iterations the soft output is transferred through the gate 17 to decision block 18, where a bit decision will be made based on the soft output.

As stated above, the bit stream output from the turbo decoder 8 passes through the shift register 9 and becomes byte oriented output, which will be sent to the RS decoder 11.

The first stage of the RS decoder (FIG. 4) is syndrome calculation 19, wherein a set of cumulative “sums” of the data in a given RS block is computed. The number of syndromes is equal to the number of error-checking data bytes in the block. If all the syndromes are equal to zero the RS decoder will stop immediately, since this indicates that no error has been detected.

The second stage 21 consists of computing an error locator polynomial, using the syndromes to determine the coefficients thereof. The error locations are determined by evaluating the error locator polynomial. If the number of errors is less than half of the number of error check bytes in the RS code word, the error locator polynomial will give all of the error locations. Otherwise, an “uncorrectable error” indicator 22 will be given, which indicates that the number of errors in the RS code word is too large to be corrected by the RS decoder.

In the next stage 23, the magnitudes of the errors are calculated using the error syndromes and the roots of the error locator polynomial.

In the final stage 24, the error magnitudes are used to convert the corrupted transmitted data back into the original data.

According to the present invention, instead of running the turbo decoder and the RS decoder independently, initial results from the RS decoder are used to control the number of iterations performed by the turbo decoder, thereby reducing the power consumed by unnecessary iterations.

According to the first embodiment of the present invention (see FIG. 5), the turbo decoder 8 functions the same way as the conventional turbo decoder discussed above, using a first decoder 12, an interleaver 13, a second decoder 14, a de-interleaver 16, and a decision block 18.

As before a bit-to-byte shift register 9 converts the data bits into data bytes for transmission to the RS decoder 11. However, unlike the conventional decoders, a logic control circuit 26 is connected between the turbo decoder 8 and the RS decoder 11, whereby the turbo decoder 8 will be stopped if any one of the following conditions is satisfied: 1) All of the syndromes calculated during the syndrome calculation step 19 are zero; 2) The uncorrectable error indicator 22 from the error locator polynomial stage 21 is zero, which indicates that even if there are errors in the turbo-decoder output, all of the errors in the code word are correctable by the RS decoder; and 3) The turbo decoder has already performed a given number of iterations.

The advantage of this embodiment is that the turbo decoder 8 can be stopped even if its output contains errors. Accordingly, in most cases, only one iteration of the turbo decoder will be enough. However, the disadvantage of this scheme is that half of the required RS decoder operation has to be done for each turbo-decoder iteration.

With reference to FIG. 6, the second embodiment of the present invention differs from the first embodiment in that decoding in the second decoder 14 is done before decoding in the first decoder 12. This arrangement enables the data output from the first decoder 12 to be fed immediately to the RS decoder 11, in which the syndrome calculation can begin as soon as the first byte is outputted. Moreover, the syndrome calculation is completed at approximately the same time as the turbo-decoder iteration. In the previous embodiment all of the data would be de-interleaved in de-interleaver 16 before syndrome calculation could begin. In this embodiment the output of the first decoder is not interleaved until it is fed back to the second decoder 14. A logic control circuit 27 of this embodiment stops the turbo decoder if either one of the following conditions is satisfied: 1) All of the syndromes in the RS decoder are zero; 2) The turbo decoder has already performed a given number of iterations. As shown in FIG. 6, X data is interleaved in interleaver 32 before decoder 2.

The advantage of this embodiment is that it utilizes less circuitry for each iteration but results in, on average, an increase in the number of iterations required.

The third embodiment, as seen in FIG. 7, is very similar to the second embodiment except that instead of using the results of the syndrome calculations, a polynomial division circuit 28 using the RS generator polynomial g(X) is used, whereby if there is no errors in the data word, after all received data bytes, including error check bytes, are shifted into the division circuit, all the registers in the division polynomial g(X) should contain only zeros. Accordingly, a control logic circuit 29 of this embodiment will stop the turbo decoder 8 if either the output of the division circuit 28 is zero after the whole data block is shifted in or the turbo decoder has already performed a given number of iterations. The polynomial division circuit is much simpler than the syndrome calculation and the average number of turbo decoder iterations for this scheme is the same as for the previous scheme but an extra polynomial division circuit is required. However, if the turbo decoder iterations are stopped because the division circuit 28 indicates that the code word is error free, the RS decoder operation can be bypassed through gate 31 to reduce power consumption.

I claim:

1. A decoder for use in a data communication system for decoding a stream of data which has been convolutionally and Reed-Solomon encoded, comprising:
a trellis decoder for performing at least one iteration for decoding the stream of data;
a Reed-Solomon decoder for further decoding the encoded stream of data after the trellis decoder is stopped, and including syndrome calculating means for calculating syndromes after every iteration of the trellis decoder; and
control means for stopping the trellis decoder from performing another iteration when all of the syndromes calculated in the syndrome calculation means are zero.

2. The decoder according to claim 1, wherein said trellis decoder is a turbo decoder.

3. The decoder according to claim 2, wherein said turbo decoder is adapted to receive a stream of data from a transmitter, which includes a first encoder with normal data input, and a second encoder with interleaved data input, the transmitter output comprising X, representing the data as input; Y₁, representing the data turbo encoded; and Y₂, representing the data interleaved and turbo encoded; and
wherein the turbo decoder comprises:
a first decoder, receiving X and Y₁ after transmission from the transmitter;
an interleaver for interleaving output from the first decoder;
a second decoder receiving output from the interleaver and Y₂, after transmission from the transmitter; and
a de-interleaver for de-interleaving output from the second decoder;
wherein output from the de-interleaver is fed back to the first decoder for another iteration through the turbo decoder unless all of the syndromes calculated in the syndrome calculation means are zero.

4. The decoder according to claim 3, wherein the Reed-Solomon decoder further comprises uncorrectable error indicator means for providing an indication, after every iteration, that output from the turbo decoder contains errors that can not be corrected by the Reed-Solomon decoder; and
wherein said control means stops the turbo decoder from performing another iteration if the uncorrectable error indicator means indicates that output from the turbo decoder does not contain any uncorrectable errors.

5. The decoder according to claim 2, wherein said turbo decoder is adapted to receive a stream of data from a transmitter, which includes a first encoder with normal data input, and a second encoder with interleaved data input, the transmitter output comprising X, representing the data as input; Y₁, representing the data turbo encoded; and Y₂, representing the data interleaved and turbo encoded; and
wherein said turbo decoder comprises:
a first decoder, receiving X and Y₂ after transmission from the transmitter;
a de-interleaver for de-interleaving output from the first decoder;
a second decoder, receiving output from the de-interleaver and Y₁, after transmission from the transmitter; and
an interleaver for interleaving output from the second decoder for input into the first decoder for another iteration through the turbo decoder;
whereby output from the second decoder is received in the Reed-Solomon decoder without having to be de-interleaved, thereby enabling the syndrome calculations means to finish calculating syndromes at substantially the same time as the turbo decoder finishes an iteration.

6. A decoder for use in a data communication system for decoding a stream of data which has been convolutionally and Reed-Solomon encoded, comprising:
a trellis decoder for performing at least one iteration for decoding the stream of data;
a division circuit means using Reed-Solomon polynomial g(x); and
control means for stopping the trellis decoder from performing another iteration when output from the division circuit means is zero after the entire decoded data stream is shifted therein; and
a Reed-Solomon decoder for further decoding the encoded stream of data after the trellis decoder is stopped.

7. The decoder according to claim 6, wherein the Reed-Solomon decoder is bypassed if the turbo decoder is stopped when output from the division circuit is zero.

8. The decoder according to claim 1, further comprising a bit-to-byte shift register between said trellis decoder and said Reed-Solomon decoder for converting output from the trellis decoder from bits to bytes, which are input into the Reed-Solomon decoder.

9. The decoder according claim 1, wherein said control means stops the trellis decoder from performing another iteration if the trellis decoder has already performed a preset number of iterations.

10. A method for use in a data communication system for decoding a stream of data which has been convolutionally and Reed-Solomon encoded, comprising the steps of:
trellis decoding the stream of data during at least one iteration through a trellis decoder;
calculating Reed-Solomon syndromes after every iteration of the trellis decoder;
stopping the trellis decoder from performing another iteration if all of the Reed-Solomon syndromes are zero; and
Reed-Solomon decoding the encoded stream of data, after the trellis decoder is stopped, in a Reed-Solomon decoder.

11. The method according to claim 10, wherein said trellis decoding comprises turbo decoding in a turbo decoder.

12. The method according to claim 11, wherein said turbo decoder is adapted to receive a stream of data from a transmitter, which includes a first encoder with normal data input, and a second encoder with interleaved data input, the transmitter output comprising X, representing the data as input; Y₁, representing the data turbo encoded; and Y₂, representing the data interleaved and turbo encoded; and
wherein the turbo decoding step comprises:
decoding X and Y₁ after transmission from the transmitter in a first decoder;
interleaving output from the first decoder;
decoding output from the interleaver and Y₂, after transmission from the transmitter;
de-interleaving output from the second decoder; and
sending output from the de-interleaver back to the first decoder for another iteration through the turbo decoder unless all of the syndromes calculated in the syndrome calculation means are zero.

13. The method according to claim 12, further comprising determining, after every iteration of the turbo decoder, whether the output from the turbo decoder contains errors that can not be corrected by the Reed-Solomon decoder; and stopping the turbo decoder from performing another iteration if the output from the turbo decoder does not contain any uncorrectable errors.

14. The method according to claim 11, wherein said turbo decoder is adapted to receive a stream of data from a transmitter, which includes a first encoder with normal data input, and a second encoder with interleaved data input, the transmitter output comprising X, representing the data as input; Y₁, representing the data turbo encoded; and Y₂, representing the data interleaved and turbo encoded; and
wherein said turbo decoding step comprises:
decoding X and Y₂ after transmission from the transmitter in a first decoder;
de-interleaving output from the first decoder in a de-interleaver;
decoding output from the de-interleaver and Y₁, after transmission from the transmitter in a second decoder; and
interleaving output from the second decoder for input into the first decoder for another iteration through the turbo decoder;
whereby output from the second decoder is received in the Reed-Solomon decoder without having to be de-interleaved, thereby enabling the syndrome calculations means to finish calculating syndromes at substantially the same time as the turbo decoder finishes an iteration.

15. A method for use in a data communication system for decoding a stream of data which has been convolutionally and Reed-Solomon encoded, comprising:
trellis decoding the stream of data during at least one iteration;
passing the stream of data through a division circuit means using a Reed-Solomon polynomial g(x);
stopping the trellis decoder from performing another iteration when output from the division circuit means is zero; and
Reed-Solomon decoding the encoded stream of data after the trellis decoder is stopped.

16. The method according to claim 15, further comprising bypassing the Reed-Solomon decoder if the turbo decoder is stopped when output from the division circuit is zero.

17. The method according to claim 10, further comprising converting output from the trellis decoder in a bit-to-byte shift register for input into said Reed-Solomon decoder.

18. The method according to claim 10, further comprising stopping the trellis decoder from performing another iteration if the trellis decoder has already performed a preset number of iterations.
